(19) United States
(12) Patent Application Publication
(10) Pub. No.: US 2026/0259135 A1
(43) Pub. Date: Sep. 3, 2026

(54) SIGNAL DETECTION DEVICE AND SIGNAL DETECTION METHOD

(71) Applicant: OSAKA UNIVERSITY, Osaka (JP)

(72) Inventors: Li YI, Osaka (JP); Masayuki FUJITA, Osaka (JP); Ryoko MIZUNO, Osaka (JP)

(21) Appl. No.: 18/995,602

(22) PCT Filed: Aug. 7, 2023
(86) PCT No.: PCT/JP2023/028669

§ 371 Date: Jan. 16, 2025

(30) Foreign Application Priority Data
Aug. 19, 2022 (JP) 2022-131358

(51) Int. Cl. G01N 21/3581

(52) U.S. Cl. CPC G01N 21/3581; G01N 2201/021

(57) ABSTRACT

A configuration of a signal detection device is simplified. A signal detection device (100) includes: a resonant tunneling diode (RTD) configured to output an output signal by (i) irradiating a target object (TG) with a terahertz wave and (ii) receiving the terahertz wave that is reflected by the target object (TG); a detection section (20A) configured to detect the output signal from the RTD (1); and a voltage supply section (11A) configured to supply the RTD (1) with DC voltage and AC voltage.

### TECHNICAL FIELD

An aspect of the present invention relates to a signal detection device that detects an output signal from a resonant tunneling diode (RTD).

### BACKGROUND ART

Non-Patent Literature 1 below discloses an example (terahertz imaging system) of the signal detection device that is made by the inventors of the present application (hereinafter, simply referred to as “the inventors”).

### CITATION LIST

### Non-Patent Literature

### [Non-Patent Literature 1]

Li Yi, Yosuke Nishida, Tomoki Sagisaka, Ryohei Kaname, Ryoko Mizuno, Masayuki Fujita, and Tadao Nagatsuma, Towards Practical Terahertz Imaging System With Compact Continuous Wave Transceiver, JOURNAL OF LIGHTWAVE TECHNOLOGY, VOL. 39, NO. 24, pp. 7850-7861, 2021

### SUMMARY OF INVENTION

### Technical Problem

An object of an aspect of the present invention is to simplify a configuration of a signal detection device.

### Solution to Problem

In order to solve the above problem, a signal detection device in accordance with an aspect of the present invention includes: an RTD configured to output an output signal by (i) irradiating a target object with a terahertz wave and (ii) receiving the terahertz wave that is reflected by the target object; a detection section configured to detect the output signal from the RTD; and a voltage supply section configured to supply the RTD with DC voltage and AC voltage.

Further, in order to solve the above problem, a signal detection method in accordance with an aspect of the present invention, which uses an RTD configured to output an output signal by (i) irradiating a target object with a terahertz wave and (ii) receiving the terahertz wave that is reflected by the target object, is configured to include the steps of: detecting the output signal from the RTD; and supplying the RTD with DC voltage and AC voltage.

### Advantageous Effects of Invention

An aspect of the present invention makes it possible to simplify a configuration of a signal detection device.

### BRIEF DESCRIPTION OF DRAWINGS

FIG. 1 is a diagram illustrating transmission/reception of a signal by an RTD in accordance with an aspect of the present invention.

FIG. 2 is a diagram illustrating an example of a current-voltage characteristic of the RTD.

FIG. 3 is a diagram illustrating an example of a configuration of a signal detection device in accordance with Reference Embodiment.

FIG. 4 is a diagram illustrating another example of the configuration of the signal detection device in accordance with Reference Embodiment.

FIG. 5 is a diagram illustrating an example of a configuration of a signal detection device in accordance with Embodiment 1.

FIG. 6 is a diagram illustrating an example of a configuration of a frequency filter circuit in accordance with Embodiment 1.

FIG. 7 is a diagram for illustrating each signal in the signal detection device in accordance with Embodiment 1.

FIG. 8 is a diagram for illustrating each signal related to a differential amplifier in accordance with Embodiment 1.

FIG. 9 is a diagram illustrating an example of a flow of an imaging process in Embodiment 1.

FIG. 10 is a diagram showing examples of images of a target object corresponding to a certain value of bias voltage in Embodiment 1.

FIG. 11 is a diagram showing examples of averaged images of a target object in Embodiment 1.

FIG. 12 is a diagram illustrating an example of a configuration of a signal detection device in accordance with Embodiment 2.

FIG. 13 is a diagram showing an example of an image of a target object which is obtained by the signal detection device in accordance with Embodiment 2.

FIG. 14 is a diagram illustrating an example of a configuration of a signal detection device in accordance with Embodiment 3.

FIG. 15 is a diagram showing an example of a simulation result regarding an RTD array in accordance with Embodiment 3.

FIG. 16 is a diagram showing another example of a simulation result regarding an RTD array in accordance with Embodiment 3.

### DESCRIPTION OF EMBODIMENTS

### Reference Embodiment

Prior to description of Embodiment 1, the following description will discuss a signal detection device in accordance with Reference Embodiment. For convenience of description, constituent elements (components) having the same functions as those described in Reference Embodiment are given the same reference signs in each subsequent embodiment, and description thereof will not be repeated. For simplicity, description of a known technical matter will be omitted as appropriate.

Respective numerical values of components described in the present specification are each merely an example as long as the content stays consistent. Therefore, for example, a positional relationship and a connection relationship of the components are not limited to an example illustrated in each drawing as long as the content stays consistent. Further, each drawing is not necessarily drawn according to actual scale. In the present specification, the expression “X to Y” regarding two numbers X and Y indicates “X or more and Y or less” as long as the content stays consistent.

### (Brief Description on RTD 1)

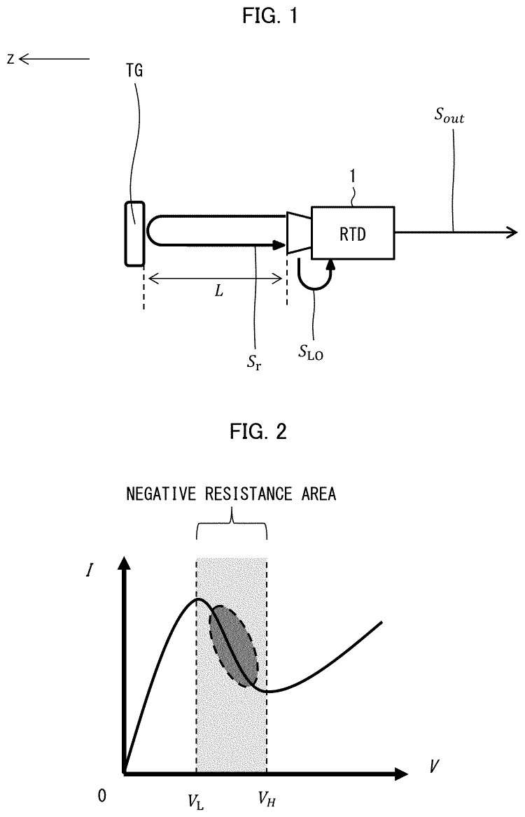

FIG. 1 is a diagram illustrating transmission/reception of a signal by an RTD (for convenience, expressed as “RTD 1”) in accordance with an aspect of the present invention. In an aspect of the present invention, the RTD 1 is used as a device in which a transmitter and a receiver are integrated with each other. Accordingly, the RTD 1 may be referred to as an RTD transceiver.

The RTD 1 irradiates a target object TG with a terahertz wave (transmission) and receives the terahertz wave that is reflected by the target object TG. The RTD 1 thus outputs an output signal.

The target object TG may be supported by a support (not illustrated). In the present specification, a direction orthogonal to a main surface of the support is referred to as “z direction”. Therefore, the z direction is an example of a depth direction of the target object. In an example illustrated in FIG. 1, the RTD 1 and the target object TG is apart from each other by a distance L in the z direction. In the example of FIG. 1, a direction in which the terahertz wave emitted from the RTD 1 is directed to the target object TG is defined as a positive direction of the z direction.

The RTD 1 may include a horn antenna for irradiation with the terahertz wave and reception of the terahertz wave. In the present specification, the terahertz wave means an electromagnetic wave that has a frequency in a terahertz band. In an example, the frequency of the terahertz wave may be 0.1 THz to 10 THz.

A reception signal Sr in the example of FIG. 1 represents the terahertz wave that is reflected by the target object TG. In the present specification, for example, in a case where Sr is to be clarified as a function of time t, the representation Sr(t) is used. Sr is expressed as:

$${S}_{r} ( t ) = {A}_{r} cos ( 2 π f ( t + \frac{2 L}{c} ) + θ ) , \qquad ( 1 )$$

where f represents a frequency, Ar represents an amplitude of the reception signal, c represents light speed, and θ represents an initial phase. The f in Sr represents an oscillation frequency of the RTD 1. The oscillation frequency of the RTD 1 belongs to the terahertz band.

FIG. 2 is a diagram illustrating an example of a current-voltage characteristic (I-V characteristic) of the RTD 1. As illustrated in FIG. 2, the current-voltage characteristic of the RTD 1 has a negative resistance area (an area where dI/dV is negative). In FIG. 2, VL and VH represent a lower limit and an upper limit of the negative resistance area, respectively.

The RTD 1 can be oscillated by supplying, to the RTD 1, a voltage that belongs to the negative resistance area (a voltage in a range of VL to VH) as a bias voltage. In other words, it is possible to cause the RTD 1 to function as a local oscillator (LO). In FIG. 2, an oval area indicates a partial area which is suitable for oscillation of the RTD 1, in the negative resistance area.

An oscillation signal SLO in the example of FIG. 1 is generated in accordance with oscillation of the RTD 1. The SLO is expressed as:

$${S}_{L O} ( t ) = {A}_{L O} cos ( 2 π ft + θ ) . \qquad ( 2 )$$

ALO represents an amplitude of the oscillation signal. The f in the SLO also represents the oscillation frequency of the RTD 1.

The RTD 1 outputs, as an output signal Sout, a signal that indicates a detection result of the RTD 1. Sout is dependent on the Ar and the ALO. Specifically, the Sout is expressed as

$$Sout = {( Sr + SLO )}^{2} . \qquad ( 3 )$$

In this way, RTD 1 outputs the output signal Sout by mixing the reception signal Sr and the oscillation signal SLO. This makes it possible to reduce the number of parts for a high frequency band, as compared with a conventional high-frequency device. This also makes it possible to simplify a wave guide circuit, as compared with a conventional high-frequency device.

Here, by expanding a right side of the above expression (3) on the basis of the expressions (1) and (2), the following is obtained:

$${S}_{out} = \frac{{A}_{LO}^{2} ( cos ( 4 π ft + 2 θ ) + 1 )}{2} + \frac{{A}_{r}^{2} ( cos ( 4 π f ( t + \frac{2 L}{c} ) + 2 θ ) + 1 )}{2} + \frac{{A}_{r} {A}_{LO} ( cos ( 4 π ft + 2 π f \times \frac{2 L}{c} + 2 θ ) + cos ( 2 π f \times \frac{2 L}{c} ) )}{2} . \qquad ( 4 )$$

As shown in expression (4), the Sout is dependent on L. Therefore, for example, L can be derived on the basis of the Sout.

Note however that the Sout shown in expression (4) is complex. In light of this, in an example, a low-pass filter may be used to remove a high-frequency signal from the Sout. In this case, a low-frequency component (for convenience, expressed as VLPF) of the Sout can be obtained. The VLPF is approximatively expressed as:

$${V}_{LPF} ∝ {A}_{r} {A}_{L O} cos ( 2 π f \times \frac{2 L}{c} ) . \qquad ( 5 )$$

In a case where f is assumed to be a constant, a value of a cos argument on the right side of expression (5) can be considered to change in accordance with only L. In other words, a phase of the VLPF can be considered to be dependent on only L. Therefore, for example, L can be derived on the basis of the VLPF.

For example, on the basis of a cycle of peak value of the VLPF obtained in a case where L is changed, an amount of change in L (in other words, amount of movement of the target object TG) can be derived. As described above, it is possible to obtain, from a pattern (for example, interference pattern) of the Sout which occurs in a case where L is changed, information (distance information) on distance between the RTD 1 and the target object TG.

### Example of Signal Detection Device in Accordance with Reference Embodiment

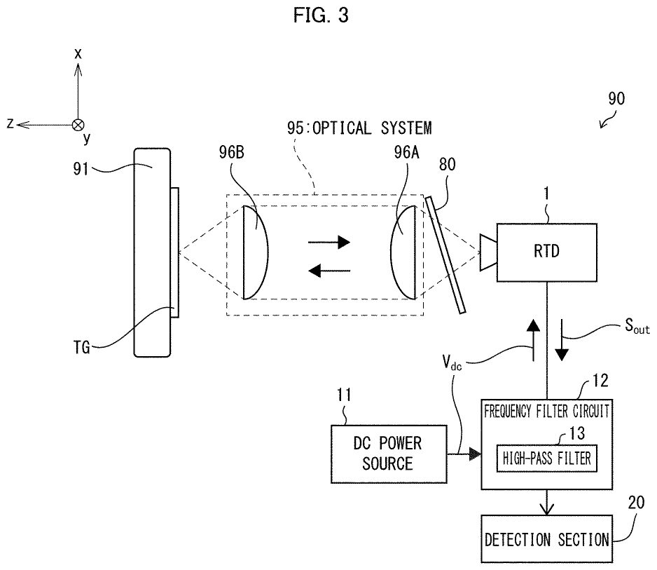

FIG. 3 illustrates an example of a configuration of a signal detection device in accordance with Reference Embodiment. The signal detection device shown in FIG. 3 is referred to as a signal detection device 90. The signal detection device 90 includes the RTD 1, a DC power source 11, a frequency filter circuit 12, a detection section 20, a spatial modulator 80, a movable stage 91, and an optical system 95. The signal detection device 90 may include a control section (not illustrated) for performing overall control of each section of the signal detection device 90.

The movable stage 91 is an example of the support. The movable stage 91 in the example of FIG. 3 may be movable in two different directions (for convenience, the directions are referred to as “x direction” and “y direction”, respectively) which are perpendicular to the z direction. In examples in the present specification, the x direction and the y direction are assumed to be orthogonal to each other. In a case where the Sout is detected while the movable stage 91 is being moved in the x direction and the y direction, it is possible to obtain a two-dimensional intensity map of the Sout. In other words, it is possible to carry out two-dimensional imaging of the target object TG.

The optical system 95 is located between the RTD 1 and the target object TG. The optical system 95 only needs to be configured to (i) guide, to the target object TG, the terahertz wave emitted from the RTD 1 and (ii) guide, to the RTD 1, the terahertz wave reflected by the target object TG. In the example of FIG. 3, the optical system 95 has a pair of lenses 96A and 96B. The lens 96A is located on an RTD 1 side, and the lens 96B is located on a target object TG side. The lens 96B is designed to guide, to the target object TG, the terahertz wave as a spot beam.

The spatial modulator 80 modulates a terahertz wave which has been emitted from the RTD 1 and the terahertz wave which is reflected by the target object TG. The spatial modulator 80 is also called a light chopper. The spatial modulator 80 may have a wheel in which a slit-shaped opening is formed in a predetermined pattern.

By rotating the wheel of the spatial modulator 80 at a predetermined speed, the spatial modulator 80 can allow the terahertz wave to pass therethrough in one or some periods (ON periods) and can block the terahertz wave in the other periods (OFF periods). In other words, the terahertz wave can be modulated at a predetermined modulation frequency (ON/OFF modulation). As is clear to a person skilled in the art, the modulation frequency corresponds to a rotation speed of the wheel of the spatial modulator 80. As described above, with the spatial modulator 80, the Sout which has been modulated can be supplied to the detection section 20. Hereinafter, even the Sout which has been modulated is also referred to as “Sout” as long as the context stays consistent.

The DC power source 11 supplies bias voltage to the RTD 1. The DC power source 11 generates DC voltage Vdc as bias voltage. In the example of FIG. 3, the DC power source 11 supplies Vdc to the RTD 1 via the frequency filter circuit 12. The DC power source 11 is an example of a voltage supply section that supplies Vdc to the RTD 1. By supplying the RTD 1 with Vdc that belongs to the negative resistance area of the RTD 1, it is possible cause the RTD 1 to oscillate.

The frequency filter circuit 12 is connected to the RTD 1, the DC power source 11, and the detection section 20. The frequency filter circuit 12 may have an internal path through which Vdc supplied from the DC power source 11 is sent out to the RTD 1. The frequency filter circuit 12 may have the high-pass filter 13. The high-pass filter 13 is located between the RTD 1 and the detection section 20.

The detection section 20 detects the Sout. With the high-pass filter 13 of the frequency filter circuit 12, it is possible to remove a low-frequency component (e.g., DC component) from the Sout and guide a high-frequency component of the Sout to the detection section 20. Thus, the detection section 20 can obtain a component having the oscillation frequency (for convenience, referred to as “oscillation component”) and a component having the modulation frequency (for convenience, referred to as “modulated component”) which are contained in the Sout. In the present specification, a frequency characteristic of the high-pass filter 13 is designed so that the high-pass filter 13 can allow the oscillation frequency component and the modulation frequency component to pass therethrough.

As described later, the detection section 20 is configured to be capable of extracting and amplifying the modulated component of the Sout. Further, the Sout detected by the detection section 20 may be associated with the amount of movement of the movable stage 91 by, for example, the control section. This makes it possible to obtain a two-dimensional intensity map of the Sout. In the example of FIG. 3, the amount of movement of the movable stage 91 in the x direction corresponds to the position of the target object TG in the x direction. Meanwhile, the amount of movement of the movable stage 91 in the y direction corresponds to the position of the target object TG in the y direction.

### Another Example of Signal Detection Device in Reference Embodiment

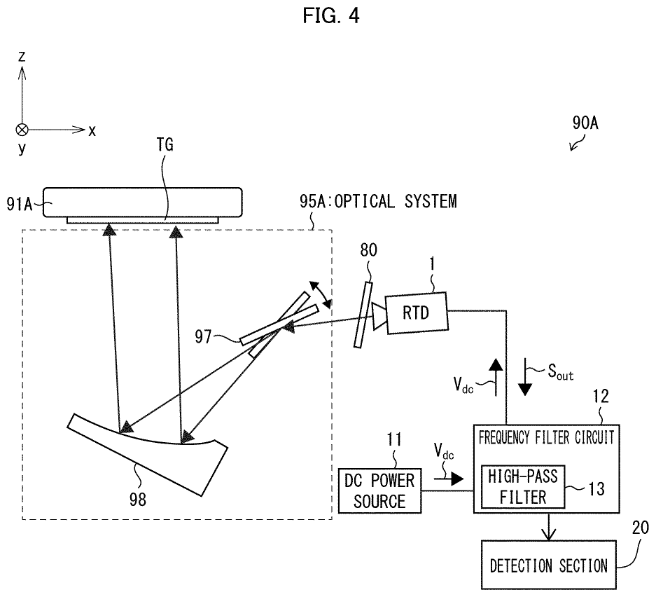

FIG. 4 shows another example of the configuration of the signal detection device in accordance with Reference Embodiment. The signal detection device illustrated in FIG. 4 is referred to as a signal detection device 90A. The signal detection device 90A has a movable stage 91A in place of the movable stage 91. The movable stage 91A may be movable in only one direction. For example, the movable stage 91A may be movable only in the y direction.

The signal detection device 90A has an optical system 95A in place of the optical system 95. In the example of FIG. 4, the optical system 95A has, as a pair of optical members, a rotation mirror 97 and a parabolic mirror 98. The rotation mirror 97 is located on the RTD 1 side. The parabolic mirror 98 has a parabolic surface that is arranged to face the target object TG.

The rotation mirror 97 reflects the terahertz wave emitted from the RTD 1 and guides the terahertz wave to the parabolic surface of the parabolic mirror 98. The parabolic surface of the parabolic mirror 98 reflects the terahertz wave which has entered from the rotation mirror 97 and directs, as a spot beam, the terahertz wave to the target object TG.

Then, the parabolic surface of the parabolic mirror 98 reflects the terahertz wave from the target object TG and guides the terahertz wave to the rotating mirror 97. The rotation mirror 97 reflects the terahertz wave that enters from the parabolic mirror 98, and guides the terahertz wave to the RTD 1.

The rotation mirror 97 may be designed to be rotatable in a predetermined direction. The rotation mirror 97 in the example of FIG. 4 is a galvano mirror. However, for example, a polygon mirror may be used as the rotation mirror 97.

The rotation mirror 97 in the example of FIG. 4 is rotatable with respect to x-axis. Therefore, by changing an angle of the rotation mirror 97, it is possible to guide the terahertz wave to different positions of the target object TG in the x direction. Therefore, the signal detection device 90A can also obtain a two-dimensional intensity map of the Sout.

In the example of FIG. 4, the Sout that is detected by the detection section 20 may be associated, for example, by the control section, with an amount of movement of the movable stage 91A and the angle of the rotation mirror 97. This makes it possible to obtain a two-dimensional intensity map of the Sout. In the example of FIG. 4, the amount of movement of the movable stage 91A corresponds to the position of the target object TG in the y direction. Then, the angle of the rotation mirror 97 corresponds to the position of the target object TG in the x direction.

According to the configuration of the signal detection device 90A of FIG. 4, the movable stage can have a simplified design as compared with the example of FIG. 3. On the other hand, according to the configuration of the signal detection device 90 of FIG. 3, the optical system can have a simplified design as compared with the example of FIG. 4.

### Embodiment 1

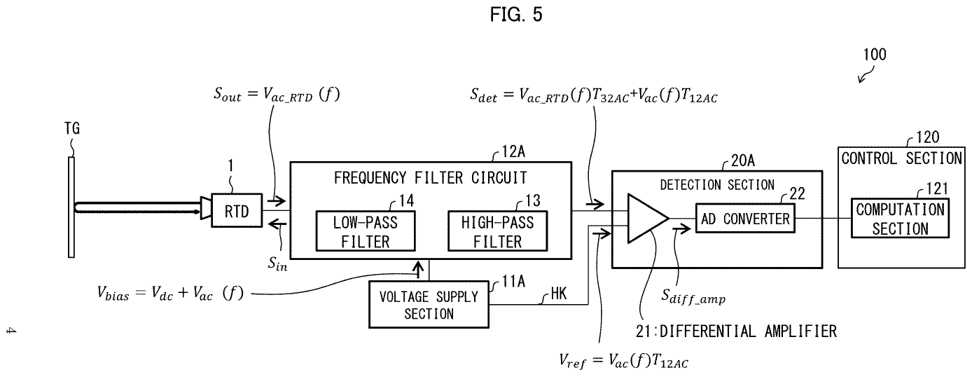

FIG. 5 is a diagram illustrating an example of a configuration of a signal detection device 100 in accordance with Embodiment 1. The signal detection device 100 has a voltage supply section 11A in place of the DC power source 11 in Reference Embodiment. The signal detection device 100 has a detection section 20A in place of the detection section 20 in Reference Embodiment. The detection section 20A may have a differential amplifier 21 and an AD converter 22.

The signal detection device 100 may have a frequency filter circuit 12A in place of the frequency filter circuit 12 in Reference Embodiment. The frequency filter circuit 12A may be connected to an RTD 1, the voltage supply section 11A, and the detection section 20A. The frequency filter circuit 12A may have a high-pass filter 13 that is located between the RTD 1 and the detection section 20A. The frequency filter circuit 12A may further have a low-pass filter 14.

The signal detection device 100 may have a supplementary path HK, which connects the voltage supply section 11A and the detection section 20A (more specifically, the differential amplifier 21) without the frequency filter circuit 12 therebetween. The signal detection device 100 may have a control section 120 that carries out overall control of each section of the signal detection device 100. The control section 120 may have a computation section 121.

The signal detection device 100 may have, between the RTD 1 and the target object TG, an optical system (e.g., the optical system described in Reference Embodiment) which is not illustrated. The signal detection device 100 may have a support (not illustrated) that supports the target object TG. In an example, the signal detection device 100 may have, as the support, a movable stage which has been described in Reference Embodiment.

The voltage supply section 11A supplies DC voltage and AC voltage to the RTD 1. In this regard, the voltage supply section 11A is different from the DC power source 11 in Reference Embodiment. In the example of FIG. 5, the voltage supply section 11A supplies the DC voltage and the AC voltage to the RTD 1 through the frequency filter circuit 12A.

Therefore, as illustrated in FIG. 5, the voltage supply section 11A may generate a bias voltage Vbias, which is expressed as follows:

$$Vbias = Vdc + Vac ( f ) . \qquad ( 6 )$$

In the example of FIG. 5, the voltage supply section 11A supplies the Vbias to the frequency filter circuit 12A. In this way, the voltage supply section 11A may generate Vbias in which the DC voltage and the AC voltage are superimposed on each other.

As described in Reference Embodiment, with the DC voltage Vdc, it is possible to cause the RTD 1 to oscillate. In addition, as described later, with AC voltage Vac(f), it is possible to modulate an output signal Sout. Therefore, in Embodiment 1, the frequency f of the Vac(f) is referred to as “modulation frequency”. The modulation frequency in Embodiment 1 belongs to a kilohertz band. In an example, the modulation frequency in Embodiment 1 is set to 1 kHz.

According to the configuration of FIG. 5, an input signal Sin corresponding to Vbias is supplied to the RTD 1 from the frequency filter circuit 12. The Sin will be described later. The RTD 1 generates an output signal Sout corresponding to the Sin. In the example of FIG. 5, for convenience of description, the Sout is also expressed as Vac_RTD(f).

The RTD 1 outputs the Vac_RTD(f) to the frequency filter circuit 12A. By causing the Vac_RTD(f) to pass through the frequency filter circuit 12A, a detection signal Sdet corresponding to the Vac_RTD(f) can be obtained. The frequency filter circuit 12A supplies the detection signal Sdet to the detection section 20A. The Sdet will be described later.

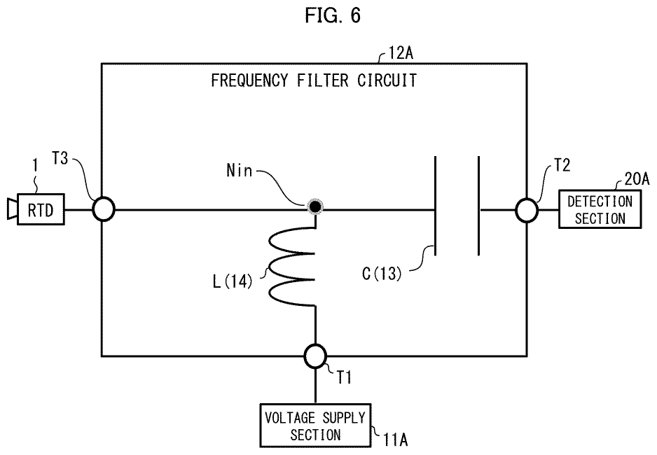

FIG. 6 shows an example of a configuration of the frequency filter circuit 12A. As illustrated in FIG. 6, the frequency filter circuit 12A may be a three-terminal circuit. Thus, the frequency filter circuit 12A may be, for example, a bias tee. Therefore, for example, the frequency filter circuit 12A can be realized with use of a commercially available bias tee.

The frequency filter circuit 12A may include a first terminal T1 connected to the voltage supply section 11A, a second terminal T2 connected to the detection section 20A, and a third terminal T3 connected to the RTD 1. Further, the frequency filter circuit 12A may include an internal node Nin that is connected to the first terminal T1, the second terminal T2, and the third terminal T3.

The high-pass filter 13 in the frequency filter circuit 12A may be located between the internal node Nin and the second terminal T2. Therefore, the frequency filter circuit 12A may have a capacitor C between the internal node Nin and the second terminal T2. The capacitor C serves as the high-pass filter 13.

The low-pass filter 14 in the frequency filter circuit 12A may be located between the internal node Nin and the first terminal T1. Therefore, the frequency filter circuit 12A may have an inductor L between the internal node Nin and the first terminal T1. The inductor L serves as the low-pass filter 14.

In the present specification, for example, a transmittance of a DC signal (e.g., DC voltage) from the first terminal T1 to the second terminal T2 in the frequency filter circuit 12A is expressed as “T12DC”. Further, for example, the transmittance of the AC signal (e.g., AC voltage) from the first terminal T1 to the second terminal T2 is expressed as “T12AC”.

As can be understood from the above-described Reference Embodiment, in a conventional signal detection device, it is intended that only a DC voltage is supplied from a power source (e.g., DC power source) to the RTD 1 via a frequency filter circuit (e.g., bias tee). In other words, in a conventional technology, no consideration has been given to an idea of supplying AC voltage from the power source to the RTD 1 via the frequency filter circuit.

Accordingly, in the conventional technology, for simplicity of theoretical study, characteristics of T13DC=1, T31AC=0, T32AC=1, T32DC=1, T12DC=0, T12AC=0, T21DC=0, and T21AC=0 have been assumed as ideal characteristics of the frequency filter circuit. The ideal characteristics are equivalent to the following (i) and (ii): (i) the high-pass filter 13 completely blocks the DC signal (e.g., DC voltage) while not attenuating the AC signal (e.g., AC voltage) at all; and (ii) the low-pass filter 14 completely blocks the AC signal while not attenuating the DC signal at all.

In practice, however, there is no frequency filter circuit (more specifically, neither the high-pass filter 13 nor the low-pass filter 14) that completely satisfies the ideal characteristics. For example, in practice, the high-pass filter 13 slightly attenuates the AC signal and allows the AC signal to slightly pass through the high-pass filter 13. Similarly, in practice, the low-pass filter 14 slightly attenuates the DC signal and allows the AC signal to slightly pass the low-pass filter 14.

The inventors have found a unique idea of “supplying DC voltage and AC voltage to the RTD 1”. This idea was obtained by directing the inventor's attention to actual characteristics of the high-pass filter 13 and the low-pass filter 14 described above. This idea is contrary to the above assumption in the conventional technology, and therefore, it can be said that the idea is a novel idea which could not be easily conceived of from the conventional technology.

In light of the above idea, examination based on the actual characteristics of the frequency filter circuit 12A will be made in the following description. With regard to the actual characteristics of the frequency filter circuit 12A, the following relation is true for the transmittance of the DC signal:

$$0 < T 13 DC , T 32 DC , T 12 DC , T 21 DC < 1. \qquad ( 7 )$$

Similarly, with regard to the actual characteristics of the frequency filter circuit 12A, the following relation is true for the transmittance of the AC signal,

$$0 < T 31 AC , T 32 AC , T 12 AC , T 21 AC < 1. \qquad ( 8 )$$

In an example described below, the transmittance of each DC signal and the transmittance of each AC signal are assumed to be given as respective known values.

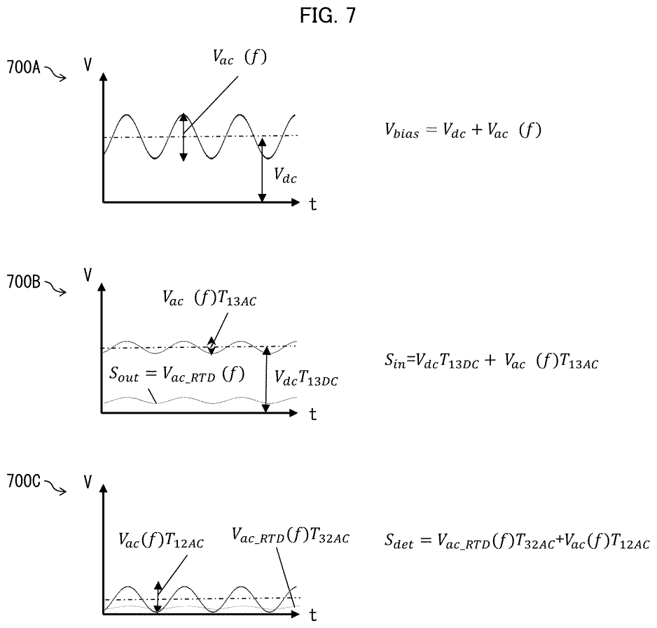

FIG. 7 is a diagram for illustrating each signal in the signal detection device 100. In FIG. 7, reference sign 700A represents a diagram for illustrating Vbias. The Vbias is expressed as expression (6) described above. The reference sign 700A shows an example of a waveform of Vdc and Vac(f).

In FIG. 7, reference sign 700B represents a diagram for illustrating Sin. The reference sign 700B also shows, for comparison, an example of a waveform of the Sout. According to the configuration of the frequency filter circuit 12A in FIG. 6, the Vdc is inputted to the RTD 1 from the voltage supply section 11A via the first terminal T1 and the third terminal T3. Similarly, the Vac(f) is inputted to the RTD 1 from the voltage supply section 11A via the first terminal T1 and the third terminal T3.

Therefore, the Sin is expressed as

$$Sin = Vdc \times T 13 DC + Vac ( f ) \times T 13 AC . \qquad ( 9 )$$

The first term on the right side and the second term on the right side in expression (9) represent a DC component and an AC component of the Sin, respectively. The reference sign 700B shows an example of respective waveforms of the first term on the right side and the second term on the right side.

Here, an amplitude of the Vac(f) is expressed as “Vm”. In this case, the maximum value Sin(max) and the minimum value Sin(min) of the Sin are expressed, respectively, as

$$Sin ( max ) = Vdc \times T 13 DC + Vm \times T 13 AC , and \qquad ( 10 )$$

$$Sin ( min ) = Vdc \times T 13 DC - Vm \times T 13 AC . \qquad ( 11 )$$

Therefore, the Sin takes all values in a range of Sin(min) to Sin(max).

As described above, in a case where the Sin belongs to the negative resistance area, the RTD 1 oscillates. On the other hand, in a case where the Sin does not belong to the negative resistance area, the RTD 1 does not oscillate. In light of this, in Embodiment 1, the Vdc and the Vm should be set such that one of the Sin(max) and the Sin(min) belongs to the negative resistance area. In this case, in Embodiment 1, the Vdc and the Vm should be set such that the other one of the Sin(max) and the Sin(min) does not belong to the negative resistance area.

By positioning the Sin(max) and the Sin(min) as described above, the Sin belongs to the negative resistance area in one or some periods (oscillation periods) and does not belong to the negative resistance area in the other periods (non-oscillation periods). Therefore, in the non-oscillation periods, it is possible to stop oscillation of the RTD 1. In other words, only in the oscillation periods, it is possible to cause the RTD 1 to output the Sout as the oscillation signal. As described above, the Vac(f) makes it possible to modulate the Sout by the modulation frequency.

As another example, the Vdc and the Vm may be set such that both of the Sin(max) and the Sin(min) belong to the negative resistance area. In this case, the Vac(f) may be used to change oscillation intensity of the RTD 1 by the oscillation frequency f. The Sout may have a relatively high value in one or some periods and a relatively low value in the other periods. It is also possible to use such an Sout as the oscillation signal.

In FIG. 7, reference sign 700C represents a diagram for illustrating Sdet. According to the configuration of the frequency filter circuit 12A in FIG. 6, the Sout, that is, the Vac_RTD(f) is input to the detection section 20A from the RTD 1 via the third terminal T3 and the second terminal T2. Meanwhile, the Vac(f) is inputted to the detection section 20A from the voltage supply section 11A via the first terminal T1 and the second terminal T2.

Therefore, the Sdet can be expressed as

$$Sdet = Vac\_RTD ( f ) \times T 32 AC + Vac ( f ) \times T 12 AC . \qquad ( 12 )$$

In expression (12), the first term on the right side represents a component of the Sdet which is derived from the Vac_RTD(f), and the second term on the right side represents a component of the Sdet which is derived from the Vac(f). The reference sign 700C shows an example of respective waveforms of the first term on the right side and the second term on the right side. In this way, in consideration of the actual characteristics of the frequency filter circuit 12A, both of the Vac_RTD(f) and the Vac(f) contribute to the Sdet.

In the example of Embodiment 1, in order to avoid complication of the expression of the Sdet, the T12DC is assumed to be sufficiently small. Therefore, it can be assumed that a relation of Vdc×T12DC≈0 is true. Therefore, a term corresponding to the Vdc is not included in the right side of expression (12).

FIG. 5 is referred to again here. In the detection section 20A, the differential amplifier 21 obtains the Sdet via the frequency filter circuit 12A. The Sdet can be expressed as an output signal which is obtained via the frequency filter circuit 12A. As illustrated in FIG. 5, the differential amplifier 21 may have two input terminals. In the example of FIG. 5, the Sdet is inputted to one of the input terminals (e.g., positive input terminal) of the differential amplifier 21.

As illustrated in FIG. 5, the voltage supply section 11A may further generate a reference voltage Vref. Vref may be a voltage corresponding to Vac(f). As described below, the Vref may be used to remove, from the Sdet, a component which is derived from the Vac(f).

In an example, the voltage supply section 11A may generate a Vref that is given as:

$$Vref = Vac ( f ) \times T 12 AC . \qquad ( 13 )$$

In other words, the voltage supply section 11A may generate a Vref equal to the second term on the right side of the Sdet shown in expression (12).

The voltage supply section 11A supplies the Vref to the differential amplifier 21 via the supplementary path HK. Therefore, the differential amplifier 21 obtains the Vref via the supplementary path HK. In the example of FIG. 5, the Vref is inputted to the other one of the input terminals (e.g., negative input terminal) of the differential amplifier 21.

The differential amplifier 21 amplifies a differential signal Sdiff between the Sdet and the Vref. The Sdiff in Embodiment 1 is expressed as

$$\begin{matrix}Sdiff = Sdet + Vref \\ = Vac\_RTD ( f ) \times T 32 AC\end{matrix} . \qquad ( 14 )$$

The differential amplifier 21 generates, by amplifying the Sdiff, a differential signal Sdiff_amp after amplification. In other words, the differential amplifier 21 generates, on the basis of the Sdiff, the following:

$$\begin{matrix}Sdiff\_amp = K \times Sdiff \\ = K \times Vac\_RTD ( f ) \times T 32 AC\end{matrix} . \qquad ( 15 )$$

K represents a gain of the differential amplifier 21.

The differential amplifier 21 supplies the Sdiff_amp to the AD converter 22. The AD converter 22 converts the Sdiff_amp from an analog value to a digital value. The AD converter 22 supplies, to the computation section 121, the Sdiff_amp which has been converted into a digital value. Thus, the computation section 121 can carry out various processes on the Sdiff_amp as the digital value.

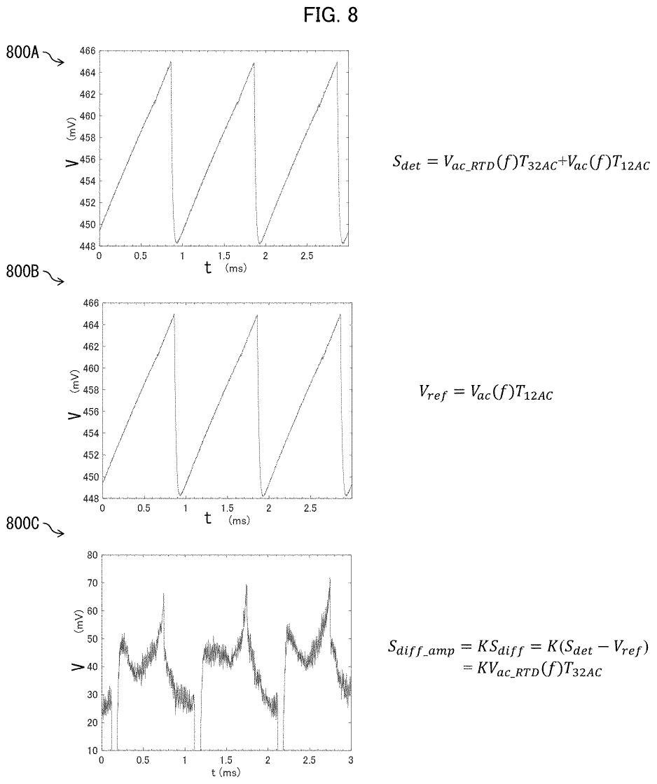

FIG. 8 is a diagram for illustrating each signal related to the differential amplifier 21. In FIG. 8, in a diagram indicated by reference sign 800A, an example of a waveform of the Sdet is shown, and in a diagram indicated by reference sign 800B, an example of a waveform of the Vref is shown. As understood from the waveforms in the diagrams indicated by the reference signs 800A and 800B, in the Sdet illustrated in expression (12), the first term on the right side is considerably smaller than the second term on the right side. In other words, the Vac_RTD(f) is fairly small.

Therefore, in the signal detection device 100, in order to extract the Vac_RTD(f), in other words, in order to remove the second term on the right side of the Sdet, the Vref is supplied to the differential amplifier 21. Then, in order to amplify the Vac_RTD(f), the Sdiff_amp is generated in the differential amplifier 21.

In FIG. 8, in a diagram indicated by reference sign 800C, an example of a waveform of the Sdiff_amp is shown. As understood from the waveform in the diagrams indicated by the reference signs 800A and 800C, the Sdiff_amp is sufficiently larger than the first term on the right side of the Sdet. In other words, the Sdiff_amp is sufficiently larger than the Vac_RTD(f). In this way, the differential amplifier 21 makes it possible to sufficiently amplify the Vac_RTD(f).

As described above, the signal detection device 100 makes it possible to extract Vac_RTD(f) from the Sdet and to amplify the Vac_RTD(f) extracted. Therefore, even in a case where the Vac_RTD(f) is small, the Vac_RTD(f) can be appropriately detected. Specifically, it is possible to detect a modulated component of the ac_RTD(f).

Note that the Sdiff_amp may be integrated over a predetermined integration period (for convenience, referred to as Δt). An integral computation of the Sdiff_amp may be carried out in the computation section 121. By integrating the Sdiff_amp over Δt, noise of the Sdiff_amp in Δt can be reduced.

Furthermore, the inventors have found that it is possible to change the oscillation frequency by changing the value of the Vbias. Therefore, by changing the value of the Vbias, it is possible to change the Sdiff_amp. In other words, by changing the value of the Vbias, it is possible to change the Sdiff.

Therefore, in the signal detection device 100, a plurality of different Vbias values may be supplied to the RTD 1. This makes it possible to obtain a plurality of Sdiffs (in other words, a plurality of Sdiff_amps) corresponding to the plurality of Vbias values. In this case, the computation section 121 may carry out a process (averaging process) of averaging the plurality of Sdiffs. Therefore, for example, the computation section 121 may average the plurality of Sdiff_amps. Examples of the averaging process will be described later.

### (Effect of Signal Detection Device 100)

As can be understood from the above description, the output signal that is outputted from the RTD 1 may be considerably smaller than other signals. Accordingly, in order to appropriately detect the output signal (e.g., to separate the output signal from noise), a method in which the output signal is modulated has been proposed. In this case, it is possible to extract a modulated component of the output signal from the signal obtained by the detection section. Therefore, as illustrated in the above-described Reference Embodiment, in the conventional signal detection device, a spatial modulator (light chopper) for modulating an output signal has been provided as an individual optical member.

In contrast, according to the signal detection device 100, DC voltage and AC voltage are supplied to the RTD 1 by the voltage supply section 11A. This makes it possible to modulate, by the AC voltage, the output signal as the oscillation signal. Therefore, unlike the conventional signal detection device, it is not necessary to provide the spatial modulator as an individual optical member. Accordingly, it is possible to simplify the configuration of the signal detection device as compared with a conventional configuration. Thus, for example, it is possible to realize a more compact signal detection device.

### Example of Imaging Process in Embodiment 1

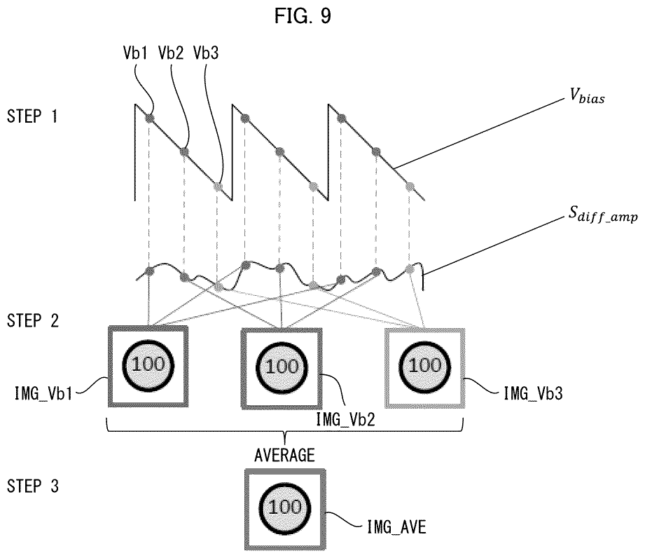

FIG. 9 is a diagram illustrating an example of a flow of an imaging process in Embodiment 1. The imaging process may be carried out by the signal detection device 100. As illustrated in FIG. 9, the imaging process may include steps 1 to 3 described below.

In step 1, Vbias is supplied to the RTD 1 by the voltage supply section 11A. In the example of FIG. 9, a sawtooth wave is used as the Vac(f) in the Vbias. The Vac(f) changes cyclically in accordance with a modulation frequency of 1 kHz. Therefore, in one cycle (1 ms section) of the Vac(f), a plurality of different Vbias values are supplied to the RTD 1.

In the example of FIG. 9, a first value Vb1, a second value Vb2, and a third value Vb3 are shown as examples of the plurality of different Vbias values in one cycle of the Vac(f). As illustrated in FIG. 9, the Vb1 to the Vb3 are each included in one cycle of the Vac(f). Therefore, over a sampling period including a plurality of cycles of the Vac(f), each of the Vb1 to the Vb3 is supplied to the RTD 1 a plurality of times.

In step 2, the computation section 121 obtains values of the Sdiff_amp each corresponding to one (same) Vbias value over the sampling period. Then, the computation section 121 reproduces, on the basis of each plurality of the values of the Sdiff_amp which are obtained as above, an image of a target object TG corresponding to the one (same) Vbias value.

For example, the computation section 121 obtains pluralities of values of Sdiff_amp. Each of the pluralities of values of Sdiff_amp correspond to one (same) Vbias supplied a plurality of times. In an example, in a case where the movable stage 91 described above is provided in the signal detection device 100, a two-dimensional position where the target object TG is irradiated with the terahertz wave may differ in accordance with a change in time.

Therefore, the computation section 121 may temporally associate each of the values of Sdiff_amp with two-dimensional coordinates (e.g., x and y coordinates). In addition, the computation section 121 may reproduce images (two-dimensional images) of the target object TG each corresponding to the one (same) Vbias supplied a plurality of times, by mapping, according to the temporal association, each of the plurality of values of Sdiff_amps to a corresponding point at the two-dimensional coordinates. FIG. 9 shows, as an example, a coin (more specifically, a Japanese 100-yen coin) which is used as the target object TG.

Accordingly, as illustrated in FIG. 9, the computation section 121 may reproduce a first image IMG_Vb1 of the target object TG on the basis of values of Sdiff_amp each corresponding to the same Vb1 supplied a plurality of times (an image of the target object TG corresponding to the same Vb1 supplied a plurality of times). Similarly, the computation section 121 may reproduce a second image IMG_Vb2 of the target object TG on the basis of values of Sdiff_amp each corresponding to the same Vb2 supplied a plurality of times (an image of the target object TG corresponding to the same Vb2 supplied a plurality of times). Further, the computation section 121 may reproduce a third image IMG_Vb3 of the target object TG on the basis of values of Sdiff_amp each corresponding to the same Vb3 supplied a plurality of times (an image of the target object TG corresponding to the same Vb3 supplied a plurality of times).

In step 3, the computation section 121 generates an averaged image by averaging a plurality of images which have been obtained in step 2. Therefore, as illustrated in FIG. 9, the computation section 121 may generate an averaged image IMG_AVE by averaging the first image IMG_Vb1 to the third image IMG_Vb3 which have been obtained in step 2. It should be noted that prior to the averaging, scaling (example: normalization) of the plurality of images having been obtained in step 2 may be carried out.

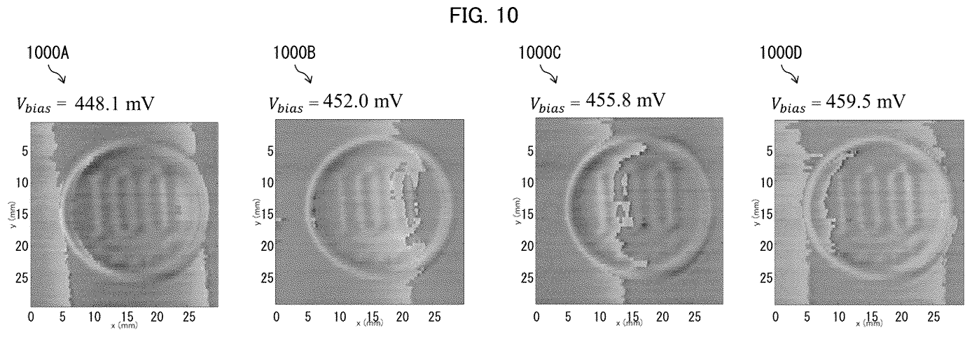

FIG. 10 shows a plurality of examples of images of the target object TG corresponding to respective certain values of the Vbias. In FIG. 10,
reference sign 1000A refers to an image of the target object TG which is obtained at Vbias=448.1 mV,
reference sign 1000B refers to an image of the target object TG which is obtained at Vbias=452.0 mV,
reference sign 1000C refers to an image of the target object TG which is obtained at Vbias=455.8 mV and
reference sign 1000D refers to an image of the target object TG which is obtained at Vbias=459.5 mV.

As described above, by changing the Vbias, the oscillation frequency of the RTD 1 is changed. Therefore, in a case where the Vbias is changed, for example, a pattern of interference fringe that when the terahertz wave reciprocates between the RTD 1 and the target object TG, occurs due to an optical path difference (in other words, a pattern of interference fringes that occur due to a phase difference of the terahertz wave) can also be changed. Therefore, as illustrated in FIG. 10, by changing the Vbias, images having different patterns can be obtained.

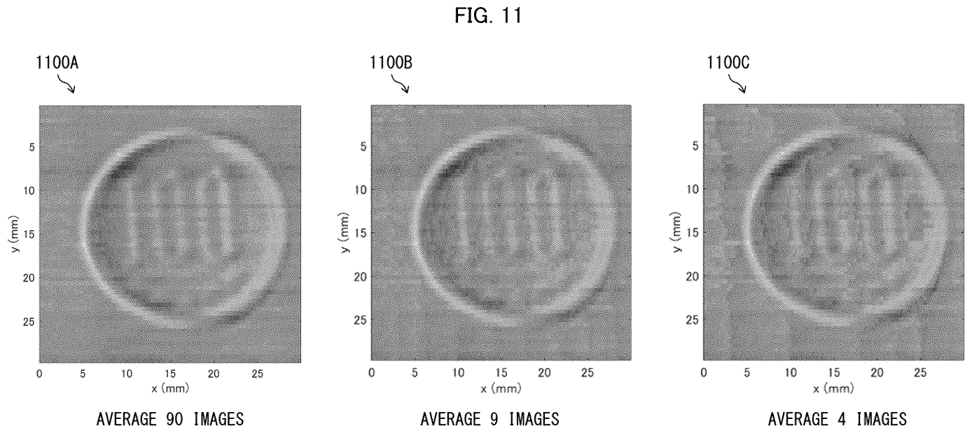

FIG. 11 shows a plurality of examples of averaged images of the target object TG. In the example of FIG. 11, in step 2 described above, 90 images (respective images of the target object TG which correspond to 90 different Vbias values) are assumed to have been obtained in advance. In a diagram represented by reference sign 1100A in FIG. 11, an averaged image obtained by averaging the 90 images is shown.

In diagrams represented by reference signs 1100B and 1100C, reference examples relative to the image in the reference sign 1100A are shown. In the reference sign 1100B, an averaged image obtained by averaging nine images out of the 90 images is shown. Further, in the reference sign 1100C, an averaged image obtained by averaging four images out of the 90 images is shown. Specifically, the image indicated by the reference sign 1100C is obtained by averaging the above-described four images shown in FIG. 10.

As is understood from FIG. 11, by averaging the plurality of images obtained (in other words, by averaging a plurality of Sdiff_amps) in step 2, it is possible to average respective patterns of interference fringes which are included in the plurality of images. As a result, it is possible to obtain an averaged image in which a pattern of interference fringes as noise is reduced. In this way, with use of the averaging process in the computation section 121, in a case where the image based on the Sdiff is reproduced, deterioration of an image due to the interference fringes can be reduced.

### Embodiment 2

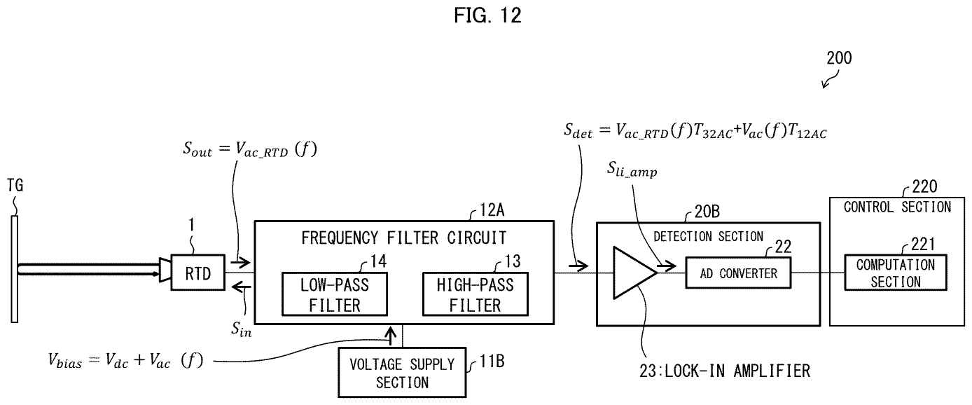

FIG. 12 is a diagram illustrating an example of a configuration of a signal detection device 200 in accordance with Embodiment 2. The signal detection device 200 has a voltage supply section 11B in place of the DC power source 11A in Embodiment 1. The voltage supply section 11B, unlike the voltage supply section 11A, may not generate a reference voltage Vref. Therefore, the signal detection device 200, unlike the signal detection device 100, may not have a supplementary path HK.

The signal detection device 200 has a detection section 20B in place of the detection section 20A in Embodiment 1. The detection section 20B has a lock-in amplifier 23 in place of the differential amplifier 21 in Embodiment 1. An Sdet is supplied from the frequency filter circuit 12A to an input terminal of the lock-in amplifier 23 in the example of FIG. 12. The lock-in amplifier 23 generates a lock-in amplification signal Sli_amp that corresponds to Sdet. Then, the lock-in amplifier 23 supplies the Sli_amp to the AD converter 22.

As is well known to a person skilled in the art, the lock-in amplifier 23 has a function of extracting and amplifying a predetermined frequency component included in a signal which is obtained by the lock-in amplifier 23 itself. Therefore, the lock-in amplifier 23 may be set to extract and amplify a modulated component (component having a modulation frequency f) which is included in an Sout. This makes it possible to appropriately detect the modulated component even in a case where the modulated component is small.

In an example, the lock-in amplifier 23 may have a function of generating the reference voltage Vref expressed by the above-described expression (13). In this case, the lock-in amplifier 23 may generate the Sli_amp, on the basis of the Sdet and the Vref as shown in:

$$SLi\_amp = KL \times ( Sdet - Vref ) . \qquad ( 16 )$$

KL in expression (16) is a gain of the lock-in amplifier 23.

Here, by transforming the expression (16), the following is obtained:

$$SLi\_amp = KL \times Vac\_RTD ( f ) \times T 32 AC . \qquad ( 17 )$$

As described above, the lock-in amplifier 23 can also extract Vac_RTD(f)×T32AC, which is a modulated component included in the Sout. Then, the modulated component can be amplified by the gain KL.

The signal detection device 200 has a control section 220 in place of the control section 120 in Embodiment 1. The control section 220 has a computation section 221. The computation section 221 acquires, from the AD converter 22, the Sli_amp after AD conversion. The computation section 221 may reproduce an image of a target object TG on the basis of the Sli_amp.

Meanwhile, as is well known to a person skilled in the art, the lock-in amplifier 23 may have a function of integrating the Sli_amp over a period Δt. According to the integration in the lock-in amplifier 23, it is possible to reduce noise of the Sli_amp. The integration in the lock-in amplifier 23 may be understood as an averaging process in Embodiment 2. Therefore, the integration in the lock-in amplifier 23 may be referred to as automatic averaging in the lock-in amplifier 23.

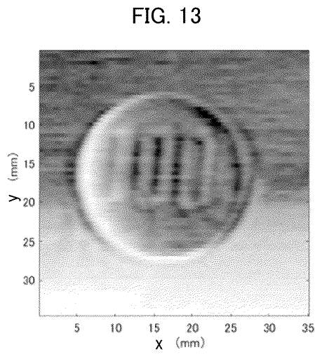

FIG. 13 shows an example of an image of the target object TG which is obtained by the signal detection device 200. The image illustrated in FIG. 13 is obtained by carrying out, by the computation section 221, two-dimensional mapping of the Sli_amp, which has been subjected to integration in the lock-in amplifier 23. The integration in the lock-in amplifier 23 can also reduce deterioration of an image of the target object TG due to interference fringes.

### Embodiment 3

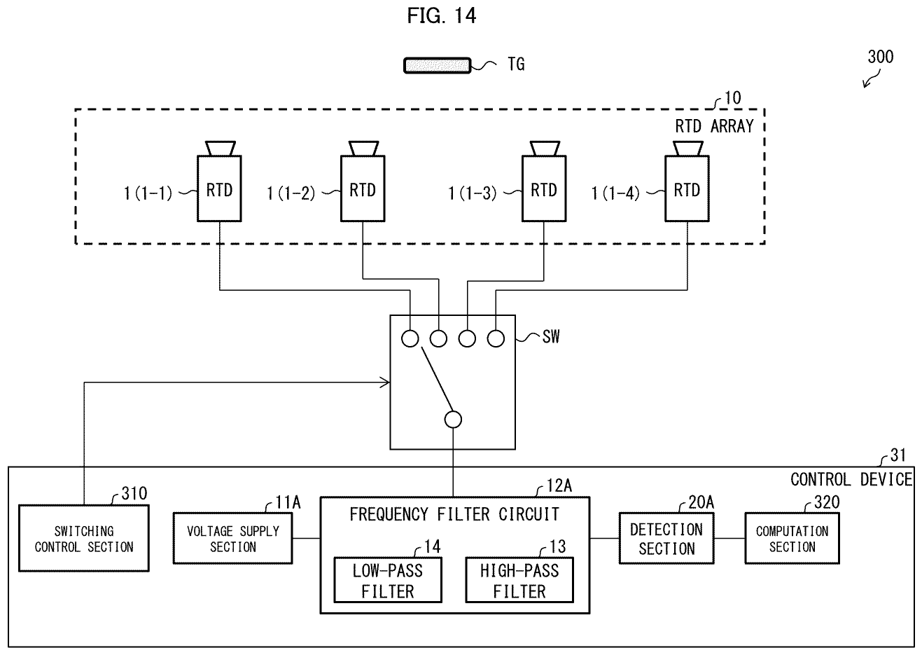

FIG. 14 is a diagram illustrating an example of a configuration of a signal detection device 300 in accordance with Embodiment 3. The signal detection device 300 may include an RTD array 10, a switch SW, and a control device 31.

The control device 31 performs overall control of each section of the signal detection device 300. The control device 31 may have, for example, the voltage supply section 11A, the frequency filter circuit 12A, and the detection section 20A which have been described in Embodiment 1. Further, the control device 31 may have a switching control section 310 and a computation section 320. The switching control section 310 generates a switching control signal for switching a connection state inside the switch SW and may supply the switching control signal to the switch SW.

The RTD array 10 includes a plurality of RTDs 1 that are arranged in an array. In the example of FIG. 14, the RTD array 10 includes four RTDs 1. In a case where each of the four RTDs 1 in FIG. 14 are to be distinguished from each other, the four RTDs 1 are referred to as RTD 1-1 to RTD 1-4, respectively. Output signals Sout that are outputted from the RTD 1-1 to RTD 1-4, respectively, are referred to as “Sout 1” to “Sout 4”, respectively.

The plurality of RTDs 1 in the RTD array 10 may be arranged one-dimensionally. In an example, the plurality of RTDs 1 may be arranged along the x direction. In this case, it is possible to obtain a one-dimensional intensity map (e.g., intensity map in the x direction) of the Sout without moving a target object TG. With use of the RTD array 10, for example, it is possible to reproduce a one-dimensional image of the target object TG without providing a movable stage.

Further, the plurality of RTDs 1 in the RTD array 10 may be arranged two-dimensionally. For example, the plurality of RTDs 1 may be disposed along each of the x direction and the y direction. In this case, it is possible to obtain a two-dimensional intensity map of the Sout without moving the target object TG. With use of the RTD array 10, for example, it is possible to reproduce a two-dimensional image of the target object TG without providing a movable stage.

The switch SW is located between the RTD array 10 and the frequency filter circuit 12A. The switch SW may make the following conductive with each other, in accordance with the switching control signal supplied from the switching control section 310: any one (e.g., RTD 1-1) of the plurality of RTDs 1 in the RTD array 10; and the frequency filter circuit 12A. In this state, the other RTDs 1 (e.g., RTDs 1-2 to 1-4) in the RTD array 10 are non-conductive with the frequency filter circuit 12A.

In this way, the switch SW can cause any one of the plurality of RTDs 1 in the RTD array 10 (for convenience, referred to as “RTD of interest”) to be connected to the frequency filter circuit 12A of the control device 31. In other words, the switch SW can selectively activate the RTD of interest. Therefore, the control device 31 can obtain, among the Sout 1 to Sout 4, one output signal (e.g., Sout 1) that corresponds to the RTD of interest. Accordingly, the control device 31 can sequentially obtain the Sout 1 to Sout 4 by controlling the switch SW. The computation section 320 may reproduce an image of the target object TG by executing an image reconstruction algorithm based on the Sout 1 to Sout 4. The image reconstruction algorithm may be a well-known algorithm in the millimeter wave imaging field.

As described above, the RTD 1 is a device in which a transmitter and a receiver are integrated with each other. In contrast, in a conventional millimeter wave imaging array, it has been common that the transmitter and the receiver are provided as separate devices. Therefore, with use of the signal detection device 300, the configuration can be simplified as compared with a device including a conventional millimeter wave imaging array.

Further, in a conventional millimeter wave imaging array, a separate switch is required to control each of the transmitter and the receiver. In contrast, with use of the signal detection device 300, a plurality of RTDs 1 in the RTD array 10 can be controlled by a single switch SW. In addition, unlike the conventional millimeter wave imaging array, control for synchronizing a transmitter and a receiver is also unnecessary. Accordingly, the signal detection device 300 makes it possible to simplify the configuration, as compared with a device including a conventional millimeter wave imaging array.

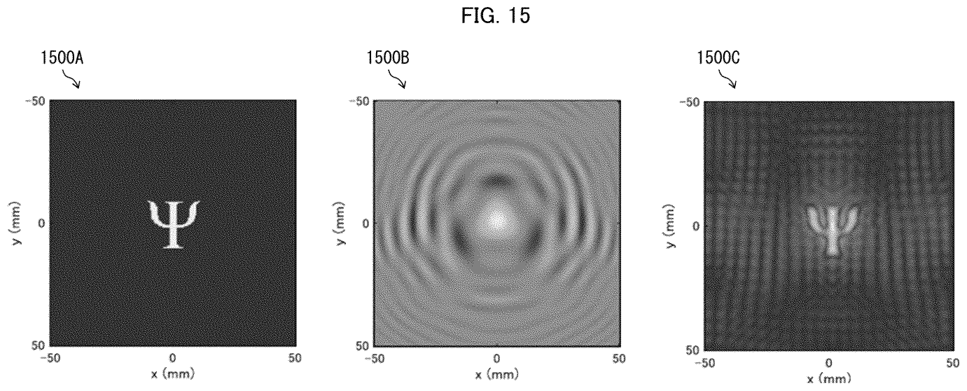

FIG. 15 shows an example of a simulation result regarding the RTD array 10. As is well known to a person skilled in the art, in order to appropriately carry out imaging by the signal detection device 300, each RTD 1 in the RTD array 10 needs to be arranged to be apart, by ½ or more of a wavelength of a predetermined terahertz wave which serves as a reference (for convenience, the wavelength of the predetermined terahertz wave is referred to as “reference wavelength”).

In the example of FIG. 15, simulation is carried out on the RTD array 10 in which the distance between the RTDs 1 is set to be equal to ½ of the reference wavelength. The RTD array 10 in the example of FIG. 15 is also referred to as a dense array. In the simulation in the example of FIG. 15, 20000 RTDs 1 are two-dimensionally arranged at equal intervals.

In FIG. 15, a diagram indicated by reference sing 1500A shows a correct answer image (simulated ground truth) in a simulation. In the simulation, a target object TG having the shape of a Greek letter Ψ is targeted.

In FIG. 15, a diagram indicated by reference sign 1500B shows an example of a two-dimensional map of an interference signal (two-dimensional map of an Sout) in the dense array. This example of the two-dimensional map is derived by the simulation. Meanwhile, a diagram indicated by reference sign 1500C shows an example of an image which is obtained by applying, to the two-dimensional map of the interference signal, an image reconstruction algorithm for a dense array (for convenience, referred to as “dense algorithm”). Examples of the dense algorithm include a general holographic process or a synthetic aperture radar process. In the following, the image obtained by the dense algorithm is also referred to as “dense reconstructed image”.

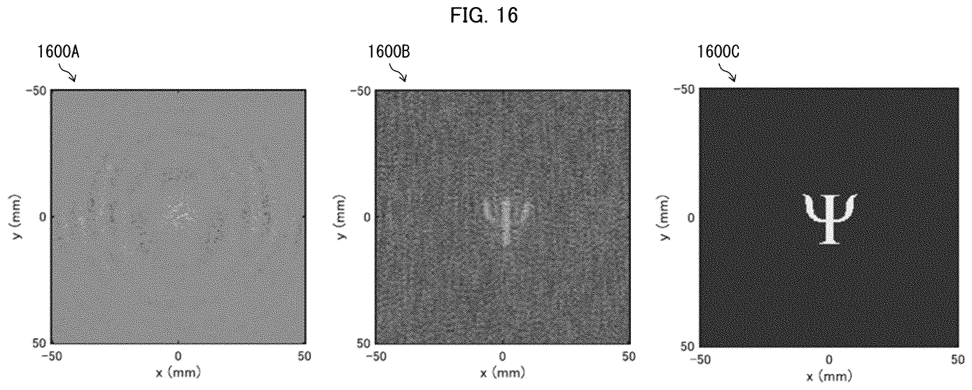

FIG. 16 shows another example of a simulation result regarding the RTD array 10. In the example of FIG. 16, a correct answer image that is same as the correct answer image in the example of FIG. 15 is used. In the example of FIG. 16, each distance between the RTDs 1 is set to be larger than that in the case of the dense array described above. The RTD array 10 in the example of FIG. 16 is also referred to as “sparse array”. In the simulation in the example of FIG. 16, 2000 RTDs 1 are two-dimensionally and unequally spaced apart from each other. In this way, the number of RTDs 1 in the sparse array is set to be 1/10 (i.e., 10%) of the number of RTDs 1 in the dense array.

In FIG. 16, a diagram indicated by reference sign 1600A shows an example of a two-dimensional map of an interference signal (two-dimensional map of an Sout) in the sparse array. This example of the two-dimensional map is derived by the simulation. Meanwhile, a diagram indicated by reference sign 1600B shows an example of an image (dense reconstructed image) that is obtained by applying a dense algorithm to the two-dimensional map of the interference signal.

As in the diagram indicated by reference sign 1600B, in a case where the dense algorithm is applied to the sparse array, noise (artifact) in the image is more noticeable than in the dense array. This noise is caused by the fact that the number of RTDs 1 in the sparse array is smaller than the number of RTDs 1 in the dense array. In other words, the noise is caused by the fact that it may be difficult in the sparse array to sample the Sout sufficient for the dense algorithm.

In light of the above, a diagram indicated by reference sign 1600C in FIG. 16 shows an example of an image that is obtained by applying, to the two-dimensional map of the interference signal, another image reconstruction algorithm (image reconstruction algorithm for the sparse array) which is different from the algorithm in the example of the reference sign 1600B. Hereinafter, the image reconstruction algorithm for a sparse array is also referred to as “sparse algorithm”. Further, an image obtained by the sparse algorithm is also referred to as “sparse reconstructed image”. Examples of the sparse algorithm include compressive sensing.

As in the diagram indicated by reference sign 1600C, with use of the sparse algorithm, it is possible to effectively reduce noise in an image. For example, with use of the sparse algorithm, it is possible to obtain a sparse reconstructed image which has higher quality than the dense reconstructed image (see the diagram indicated by the reference sign 1500C) obtained in the dense array.

From the above, it is preferable that the computation section 320 be configured to execute the sparse algorithm. In this case, since the RTD array 10 can be realized as a sparse array, a configuration of the RTD array 10 can be simplified. Therefore, for example, it is possible to reduce manufacturing cost of the RTD array 10.

### Software Implementation Example

A function of each of the signal detection devices 100 to 300 (hereinafter, referred to as “device”) can be realized by a program for causing a computer to function as the device, the program causing the computer to function as each of control blocks (particularly, the control sections 120 to 220 and each section included in the control device 31) of the device.

In this case, the device includes, as hardware for executing the program, a computer which includes at least one control device (e.g., processor) and at least one storage device (e.g., memory). By the control device and the storage device executing the program, each function described in each of the foregoing embodiments is realized.

The program may be stored in at least one non-transitory, computer-readable storage medium. This storage medium may or may not be included in the above device. In the latter case, the program may be made available to the device via any wired or wireless transmission medium.

Furthermore, some or all of functions of the control blocks can also be realized by a logic circuit. For example, the scope of the present invention also encompasses an integrated circuit in which a logic circuit that functions as the control blocks is provided. In addition, the functions of the control blocks can also be realized by, for example, a quantum computer.

The processes described in the above embodiments can be carried out by artificial intelligence (AI). In this case, AI may be operated in the control device, or may be operated in another device (e.g., an edge computer or a cloud server).

Aspects of the present invention can also be expressed as follows:

A signal detection device according to Aspect 1 of the present invention includes: an RTD configured to output an output signal by (i) irradiating a target object with a terahertz wave and (ii) receiving the terahertz wave that is reflected by the target object; a detection section configured to detect the output signal from the RTD; and a voltage supply section configured to supply the RTD with DC voltage and AC voltage.

A signal detection device according to Aspect 2 of the present invention may be configured to further include, in the above Aspect 1, a frequency filter circuit connected to the voltage supply section, the detection section, and the RTD, the detection section having a differential amplifier, the voltage supply section generating a reference voltage corresponding to the AC voltage, and the differential amplifier amplifying a differential signal between (i) the output signal obtained via the frequency filter circuit and (ii) the reference voltage obtained via a supplementary path without passage through the frequency filter circuit.

A signal detection device according to Aspect 3 of the present invention may be configured to further include, in the above Aspect 2, a computation section configured to average a plurality of the differential signals.

A signal detection device according to Aspect 4 of the present invention may be configured such that in the above Aspect 1: the AC voltage has a frequency called a modulation frequency; and the detection section has a lock-in amplifier that extracts and amplifies a component having the modulation frequency in the output signal.

A signal detection device according to Aspect 5 of the present invention may be configured to further include, in any one of the above Aspects 1 to 4, a frequency filter circuit connected to the voltage supply section, the detection section, and the RTD, the frequency filter circuit including a high-pass filter that is located between the RTD and the detection section.

A signal detection device according to Aspect 6 of the present invention may be configured such that in the above Aspect 5: the frequency filter circuit includes a first terminal connected to the voltage supply section, a second terminal connected to the detection section, a third terminal connected to the RTD, an internal node connected to the first terminal, the second terminal, and the third terminal, and a low-pass filter located between the internal node and the first terminal; and the high-pass filter is located between the internal node and the second terminal.

A signal detection device according to Aspect 7 of the present invention may be configured to further include, in any one of the above Aspects 1 to 6, a switch, the RTD including a plurality of RTDs that are arranged in an array, and the switch selectively activating any one of the plurality of RTDs.

A signal detection method according to Aspect 8 of the present invention, which uses an RTD configured to output an output signal by (i) irradiating a target object with a terahertz wave and (ii) receiving the terahertz wave that is reflected by the target object, is configured to include the steps of: detecting the output signal from the RTD; and supplying the RTD with DC voltage and AC voltage.

### ADDITIONAL REMARKS

An aspect of the present disclosure is not limited to the above embodiments, but can be altered variously by a person skilled in the art within the scope of the claims. The aspect of the present invention also encompasses, in its technical scope, any embodiment derived by appropriately combining technical means disclosed in differing embodiments.

### REFERENCE SIGNS LIST

1, 1-1 to 1-4 RTD
100, 200, 300 signal detection device
10 RTD array
11A, 11B voltage supply section
12A frequency filter circuit
13 high-pass filter
14 low-pass filter
20A, 20B detection section
21 differential amplifier
23 lock-in amplifier
121, 221, 320 computation section
TG target object
HK supplementary path
T1 first terminal
T2 second terminal
T3 third terminal
Nin internal node
SW switch

1. A signal detection device comprising:
a resonant tunneling diode (RTD) configured to output an output signal by (i) irradiating a target object with a terahertz wave and (ii) receiving the terahertz wave that is reflected by the target object;
a detection section configured to detect the output signal from the RTD; and
a voltage supply section configured to supply the RTD with DC voltage and AC voltage.

2. The signal detection device as set forth in claim 1, further comprising
a frequency filter circuit connected to the voltage supply section, the detection section, and the RTD,
the detection section having a differential amplifier,
the voltage supply section generating a reference voltage corresponding to the AC voltage, and
the differential amplifier amplifying a differential signal between (i) the output signal obtained via the frequency filter circuit and (ii) the reference voltage obtained via a supplementary path without passage through the frequency filter circuit.

3. The signal detection device as set forth in claim 2, further comprising
a computation section configured to average a plurality of the differential signals.

4. The signal detection device as set forth in claim 1, wherein:
the AC voltage has a frequency called a modulation frequency; and
the detection section has a lock-in amplifier that extracts and amplifies a component having the modulation frequency in the output signal.

5. The signal detection device as set forth in claim 1, further comprising
a frequency filter circuit connected to the voltage supply section, the detection section, and the RTD,
the frequency filter circuit including a high-pass filter that is located between the RTD and the detection section.

6. The signal detection device as set forth in claim 5, wherein:
the frequency filter circuit includes
a first terminal connected to the voltage supply section,
a second terminal connected to the detection section,
a third terminal connected to the RTD,
an internal node connected to the first terminal, the second terminal, and the third terminal, and
a low-pass filter located between the internal node and the first terminal; and
the high-pass filter is located between the internal node and the second terminal.

7. The signal detection device as set forth in claim 1, further comprising
a switch,
the RTD including a plurality of RTDs that are arranged in an array, and
the switch selectively activating any one of the plurality of RTDs.

8. A signal detection method using a resonant tunneling diode (RTD) configured to output an output signal by (i) irradiating a target object with a terahertz wave and (ii) receiving the terahertz wave that is reflected by the target object, the method comprising the steps of:
detecting the output signal from the RTD; and
supplying the RTD with DC voltage and AC voltage.
